(19) United States
(12) Patent Application Publication
(10) Pub. No.: US 2025/0350837 A1
(43) Pub. Date: Nov. 13, 2025

(54) SENSOR SHIFTING ACTUATOR AND CAMERA MODULE INCLUDING SENSOR SHIFTING ACTUATOR

(71) Applicant: Samsung Electro-Mechanics Co., Ltd., Suwon-si (KR)

(72) Inventor: Tae Won KANG, Suwon-si (KR)

(73) Assignee: Samsung Electro-Mechanics Co., Ltd., Suwon-si (KR)

(21) Appl. No.: 19/069,854

(22) Filed: Mar. 4, 2025

(30) Foreign Application Priority Data
May 8, 2024 (KR) 10-2024-0060678

(51) Int. Cl. H04N 23/68

(52) U.S. Cl. CPC H04N 23/687

(57) ABSTRACT

A sensor shifting actuator includes a housing having an internal space; an image sensor, accommodated in the housing, having an imaging surface; a first moving frame, accommodated in the housing, configured to be movable in a direction parallel to the imaging surface, together with the image sensor; a second moving frame, accommodated in the housing, configured to be movable in a direction perpendicular to the imaging surface, together with the image sensor and the first moving frame; a bridge portion configured to curve in at least a portion thereof and support a movement of the image sensor in the direction parallel to the imaging surface; and a plurality of ball members, disposed between the second moving frame and the housing, configured to support another movement of the image sensor in the direction perpendicular to the imaging surface.

### CROSS-REFERENCE TO RELATED APPLICATIONS

This application claims the benefit under 35 USC 119(a) of Korean Patent Application No. 10-2024-0060678 filed on May 8, 2024, in the Korean Intellectual Property Office, the entire disclosure of which is incorporated herein by reference for all purposes.

### BACKGROUND

### 1. Field

The present disclosure relates to a sensor shifting actuator and a camera module including the same.

### 2. Description of the Background

Recently, camera modules adopted in mobile devices are also being manufactured to have performance comparable to that of conventional cameras. For example, a camera module may be provided with focus adjustment and shake correction functions as standard.

Meanwhile, as the frequency of recording videos using mobile devices increases, the desire for camera modules that may provide high zoom ratios is increasing.

Accordingly, a high zoom ratio is implemented by having a reflector such as a prism in the camera module so that the incident light may give a relatively long total track length.

Additionally, in the camera module including the reflector, the focus adjustment function and shake correction function are implemented by moving the lens module and the reflector module, respectively.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a sensor shifting actuator includes a housing having an internal space; an image sensor, accommodated in the housing, having an imaging surface; a first moving frame, accommodated in the housing, configured to be movable in a direction parallel to the imaging surface, together with the image sensor; a second moving frame, accommodated in the housing, configured to be movable in a direction perpendicular to the imaging surface, together with the image sensor and the first moving frame; a bridge portion configured to curve in at least a portion thereof and support a movement of the image sensor in the direction parallel to the imaging surface; and a plurality of ball members, disposed between the second moving frame and the housing, configured to support another movement of the image sensor in the direction perpendicular to the imaging surface.

A sensor substrate disposed on one side of the image sensor may include a first moving portion coupled with the first moving frame, a second moving portion coupled with the second moving frame and spaced apart from the first moving portion, and the bridge portion disposed between the first moving portion and the second moving portion.

The first moving portion and the second moving portion may be formed of a rigid material, and the bridge portion may be formed of a flexible material.

The sensor shifting actuator may further include a connecting substrate configured to support movements of the image sensor, the first moving frame, and the second moving frame. One side of the connecting substrate may be connected to the sensor substrate and another side of the connecting substrate disposed in the housing.

The sensor substrate may include a first connecting portion extending from the first moving portion and connecting the first moving portion and the bridge portion, and a second connecting portion extending from the second moving portion and connecting the second moving portion and the bridge portion. The one side of the connecting substrate may be connected with the first connecting portion.

The sensor shifting actuator may further include a main substrate disposed in the housing. The other side of the connecting substrate may be coupled to the main substrate, and the connecting substrate may be disposed to surround a portion of the main substrate while maintaining a gap therebetween.

The connecting substrate may include a first portion disposed with a gap between the main substrate in a first direction parallel to the imaging surface, a second portion disposed with a gap between the main substrate in a second direction parallel to the imaging surface and perpendicular to the first direction, and a third portion disposed with a gap between the main substrate in a third direction perpendicular to the imaging surface. The first portion may be connected to the housing, and the third portion may be connected to the sensor substrate.

A surface of the main substrate may include an avoidance groove extending therethrough in the third direction in a portion overlapping with the third portion. A portion of the third portion may be disposed in the avoidance groove.

The sensor shifting actuator may further include a first shake correction magnet and a second shake correction magnet disposed on the first moving frame; and a first shake correction coil and a second shake correction coil disposed in the housing to face the first shake correction magnet and the second shake correction magnet, respectively.

The sensor shifting actuator may further include a focus adjustment magnet disposed on the second moving frame, and a focus adjustment coil disposed in the housing to face the focus adjustment magnet.

The sensor shifting actuator may further include a yoke disposed in the housing to face the focus adjustment magnet.

In another general aspect, a camera module includes a lens module comprising at least one lens disposed along an optical axis direction; an image sensor having an imaging surface; a reflective member configured to reflect light toward the image sensor; and a sensor shifting actuator configured to move the image sensor in a direction parallel to the imaging surface and a direction perpendicular to the imaging surface with respect to the reflective member. The sensor shifting actuator includes a bridge portion, disposed to be curved in at least a portion thereof, configured to support a movement of the image sensor in the direction parallel to the imaging surface, and a plurality of ball members configured to support movement of the image sensor in the direction perpendicular to the imaging surface while rolling in the direction perpendicular to the imaging surface.

The sensor shifting actuator may further include a first moving frame configured to be movable in the direction parallel to the imaging surface, together with the image sensor, and a second moving frame configured to be movable in the direction perpendicular to the imaging surface, together with the image sensor and the first moving frame.

The sensor shifting actuator may include a sensor substrate disposed on one side of the image sensor. The sensor substrate may include a first moving portion coupled with the first moving frame, a second moving portion coupled with the second moving frame and spaced apart from the first moving portion, and the bridge portion disposed between the first moving portion and the second moving portion.

The sensor shifting actuator may include a main substrate disposed in a housing in which the image sensor is accommodated, and a connecting substrate in which one side is connected to the sensor substrate and another side is connected to the main substrate. The connecting substrate may be disposed to have a gap between the main substrate in at least one direction, among the direction parallel to the imaging surface and the direction perpendicular to the imaging surface. The connecting substrate may be configured to bend in at least a portion thereof when the image sensor moves.

The reflective member may be a parallelogram shaped prism.

Other features and aspects will be apparent from the following detailed description, the drawings, and the claims.

### BRIEF DESCRIPTION OF DRAWINGS

FIG. 1 is a conceptual diagram of a camera module according to an embodiment of the present disclosure.

FIG. 2 is a diagram exemplarily illustrating the movement of an image sensor according to an embodiment of the present disclosure.

FIG. 3 is a perspective view of a sensor shifting actuator according to an embodiment of the present disclosure.

FIG. 4 is an exploded perspective view of a sensor shifting actuator according to an embodiment of the present disclosure.

FIG. 5 is a perspective view of the sensor shifting actuator with a shield can removed.

FIG. 6A is a cross-sectional view of section I-I′ of FIG. 3.

FIG. 6B is an enlarged view of partial A of FIG. 6A

FIG. 7 is a plan view of a sensor substrate according to an embodiment of the present disclosure.

FIG. 8 is a cross-sectional view of section II-II′ of FIG. 3.

FIG. 9 is a diagram illustrating a ball guide portion according to an embodiment of the present disclosure.

FIG. 10 and FIG. 11 are diagrams illustrating a connecting substrate according to an embodiment of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples. Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

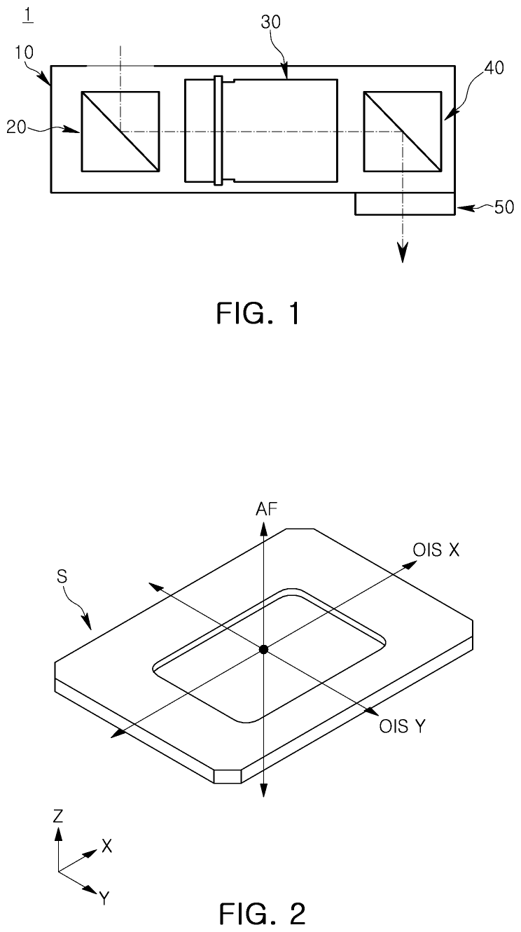

FIG. 1 is a conceptual diagram of a camera module according to an embodiment of the present disclosure.

Referring to FIG. 1, the camera module 1 may include a housing 10, a plurality of reflective modules 20 and 40, a lens module 30, and an image sensor module 50.

The housing 10 may have an internal space. A plurality of reflective modules 20 and 40 and lens modules 30 may be disposed in the internal space of the housing 10.

The lens module 30 may include a plurality of lenses aligned in an optical axis direction.

A plurality of reflective modules 20 and 40 may include a reflective member changing the path of light incident on the camera module 1. For example, the reflective member may be a prism.

The plurality of reflective modules 20 and 40 may include a first reflective module 20 disposed in front of the lens module 30 and a second reflective module 40 disposed to the rear of the lens module 30 based on a traveling path of light.

In an embodiment, the first reflective module 20 may reflect or refract light incident on the camera module 1 toward the lens module 30. Additionally, the second reflective module 40 may reflect or refract light passing through the lens module 30 toward the image sensor module 50.

According to an embodiment of the present disclosure, the camera module 1 may implement a relatively long total length by switching the traveling path of light incident on the camera module 1 at least twice.

Meanwhile, light incident on the camera module 1 may ultimately reach the image sensor module 50.

The image sensor module 50 may include an image sensor S converting light reaching the image sensor module 50 into an electrical signal.

The camera module 1 according to an embodiment of the present disclosure may be not limited to the structure illustrated in FIG. 1, and some of the configurations may be modified or omitted. For example, the shape and size of the plurality of reflective modules 20 and 40 and lens modules 30 may be changed.

According to an embodiment of the present disclosure, the camera module 1 may implement a focus adjustment function and a shake correction function by moving the image sensor S.

FIG. 2 is a diagram exemplarily illustrating the movement of an image sensor according to an embodiment of the present disclosure.

Referring to FIG. 2, the image sensor S may be moved in three mutually perpendicular axes direction.

In an embodiment of the present disclosure, the image sensor S may be moved in three mutually perpendicular axes direction about to a reflective member P to be described later.

When adjusting focus, the image sensor S may be moved in a first-axis direction (Z-axis direction) perpendicular to the imaging surface, and when correcting shake, it may be moved in two directions parallel to the imaging surface, for example, a second-axis direction (X-axis direction) parallel to a long axis direction of the image sensor S and a third-axis direction (Y-axis direction) parallel to a short axis direction of the image sensor S.

According to an embodiment of the present disclosure, the camera module 1 moves a relatively light image sensor S, such that precise focus adjustment and shake correction may be performed. In addition, power consumption may be reduced during focus adjustment and shake correction.

A camera module 1 according to an embodiment of the present disclosure may include a sensor shifting actuator 500 moving an image sensor S.

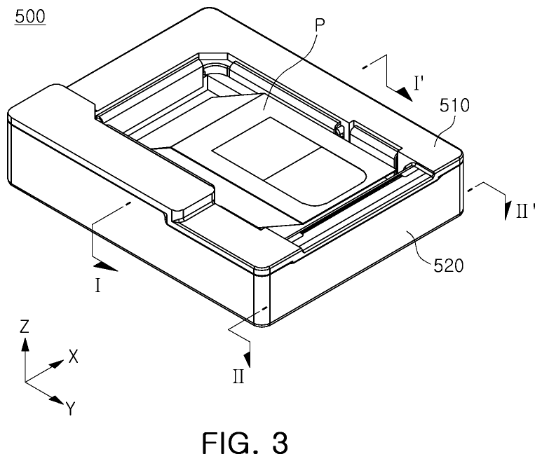

FIG. 3 is a perspective view of a sensor shifting actuator according to an embodiment of the present disclosure.

The sensor shifting actuator 500 may be applied to the image sensor module 50 of FIG. 1. For example, the sensor shifting actuator 500 may accommodate the image sensor module 50.

The sensor shifting actuator 500 may include a driving portion generating driving force to move the image sensor S in three-axis directions. For example, the driving portion may be a voice coil motor (VCM) including a magnet and a coil.

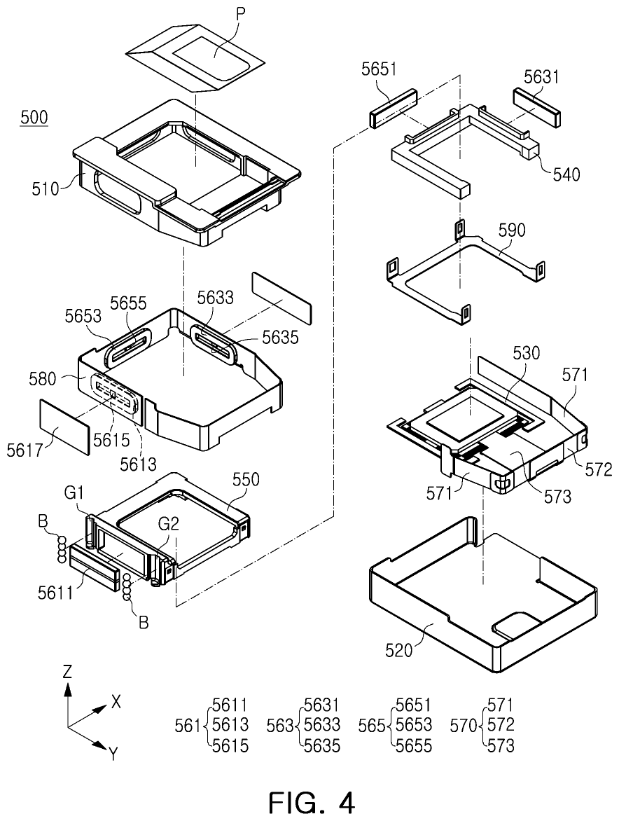

Hereinafter, referring to FIG. 4, or the like, the detailed configurations of the sensor shifting actuator 500 are described in detail.

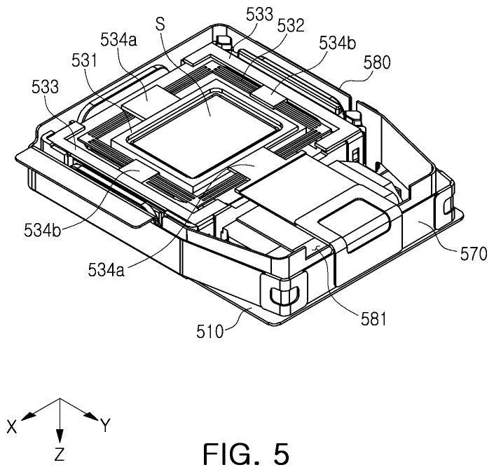

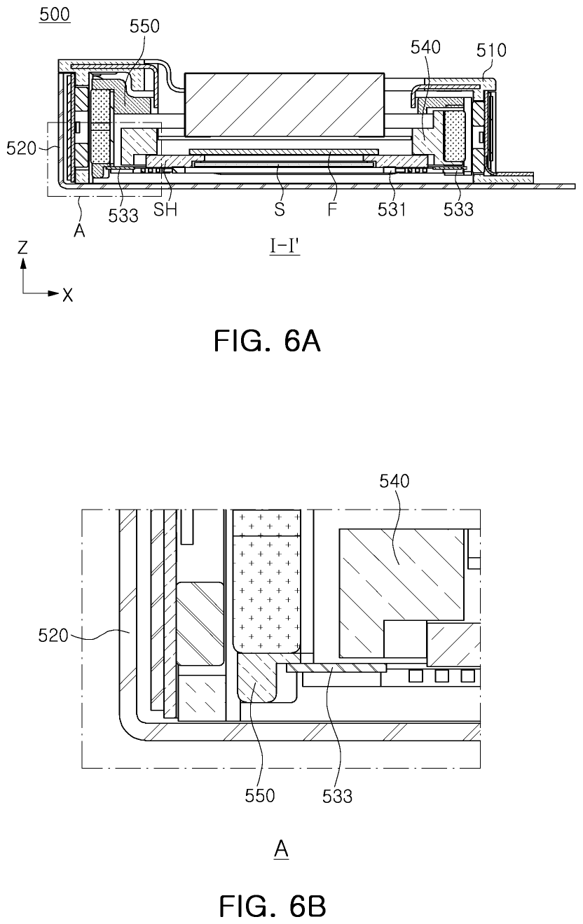

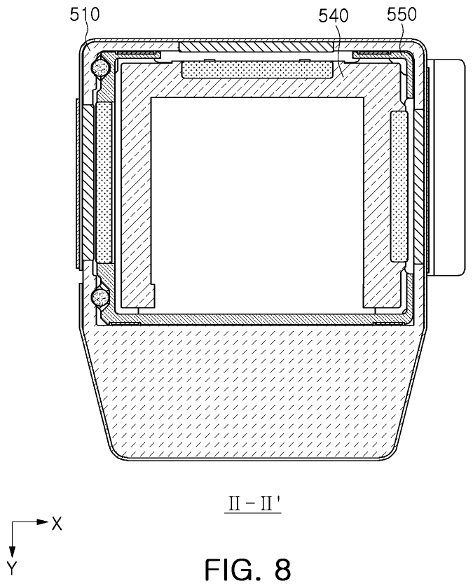

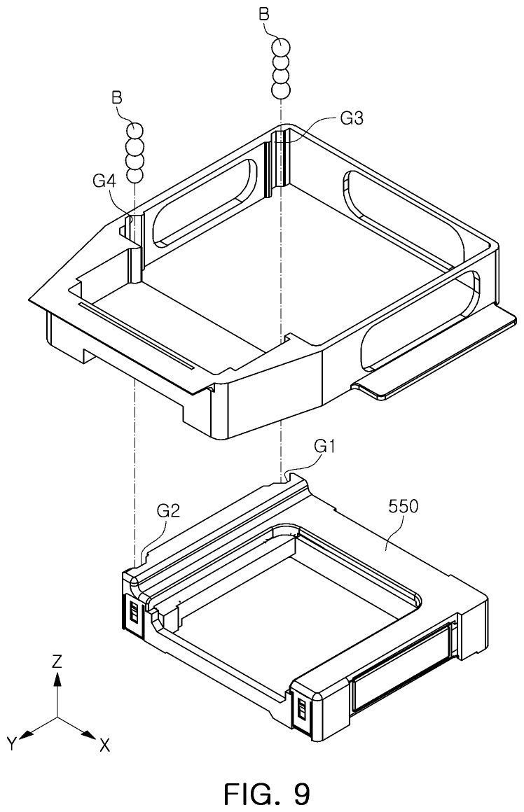

FIG. 4 is an exploded perspective view of a sensor shifting actuator according to an embodiment of the present disclosure. FIG. 5 is a perspective view of a sensor shifting actuator with the shield can removed. FIG. 6A is a cross-sectional view of section I-I′ of FIG. 3. FIG. 6B is an enlarged view of section A of FIG. 6A. FIG. 8 is a cross-sectional view of section II-II′ of FIG. 3.

Referring to FIG. 4, the sensor shifting actuator 500 may include a housing 510, a shield can 520, a sensor substrate 530, a first moving frame 540, a second moving frame 550, and a driving portion.

The housing 510 may have an internal space in which a sensor substrate 530 or the like is accommodated.

The housing 510 may have an internal space and may be opened-form in the first-axis direction (Z-axis direction).

In an embodiment, the internal space of the housing 510 may sequentially accommodate the second moving frame 550, the first moving frame 540, and the sensor substrate 530 in the first-axis direction (Z-axis direction).

Additionally, the reflective member P may be disposed on an upper side of the second moving frame 550. For example, the reflective member P may be a prism having a parallelogram shape.

The reflective member P may be a portion of the second reflective module 40 of FIG. 1. The reflective member P may be disposed in an open portion of the housing 510.

The shield can 520 may be coupled to the housing 510 to cover the interior space. For example, the shield can 520 may be coupled to the housing 510 on the opposite side of the reflective member, i.e., the sensor substrate 530 side.

The housing 510 and shield can 520 may be fixed members. Accordingly, the movement of the image sensor S, or the like, may be relative to the housing 510.

The image sensor S may be disposed on the sensor substrate 530.

In detail, referring to FIGS. 6A and 6B, the image sensor S may be disposed on the sensor substrate 530 via a sub-housing SH. That is, the sub-housing SH in which the image sensor S is disposed may be coupled with the sensor substrate 530.

In addition to the image sensor S, an optical filter F may also be disposed in the sub-housing SH. For example, an optical filter F may be disposed between the reflective member P and the image sensor S, and may block light of a specific wavelength region from among the light passing through the reflective member P and entering the image sensor S.

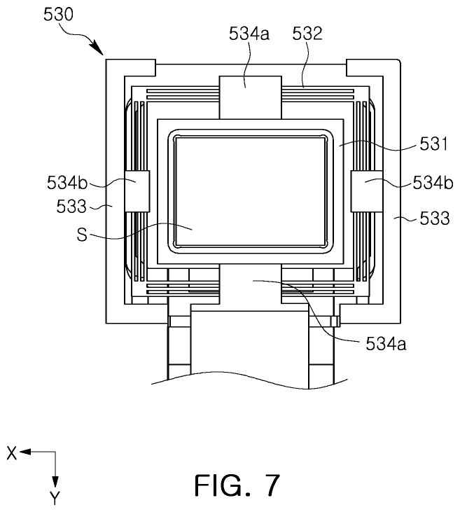

FIG. 7 is a plan view of a sensor substrate according to an embodiment of the present disclosure.

The sensor substrate 530 may include a first moving portion 531 to which a sub-housing SH is coupled, a second moving portion 533 spaced apart from the first moving portion 531, and a bridge portion 532 supporting the movement of the image sensor S.

In an embodiment, the sensor substrate 530 may be a rigid printed circuit substrate, the first moving portion 531 and the second moving portion 533 may be formed of a rigid material, and the bridge portion 532 may be formed of a flexible material.

The first moving portion 531 may be coupled with the sub-housing SH in which the image sensor S is disposed, and may be moved in three mutually perpendicular axes direction together with the image sensor S.

Referring to FIG. 6A, the sub-housing SH may be coupled with a first moving frame 540 moving in a second-axis direction (X-axis direction) and a third-axis direction (Y-axis direction) parallel to the imaging surface, and may move in the second-axis direction (X-axis direction) and the third-axis direction (Y-axis direction) together with the first moving frame 540.

In addition, since the sub-housing SH is also coupled with the first moving portion 531, the first moving portion 531 may move in the second-axis direction (X-axis direction) and the third-axis direction (Y-axis direction) together with the sub-housing SH and the first moving frame 540.

The second moving portion 533 may include two portions spaced apart in the second-axis direction (X-axis direction) with the first moving portion 531 interposed therebetween.

Referring to FIG. 6B, the second moving portion 533 may be coupled with the second moving frame 550 moving in the first-axis direction (Z-axis direction). Accordingly, the second moving portion 533 may move in the first-axis direction (Z-axis direction) together with the second moving frame 550.

In this case, although not illustrated in the drawing, a plate spring may be additionally provided to supplement the coupling rigidity of the second moving portion 533 and the second moving frame 550.

In an embodiment, the plate spring may be structurally connected by having one side disposed on the second moving portion 533 and the other side disposed on the second moving frame 550.

The plate spring may extend at least partially in the first-axis direction (Z-axis direction) to connect the second moving portion 533 and the second moving frame 550 in the first-axis direction (Z-axis direction).

Referring to FIG. 6B, the second moving portion 533 may be spaced apart from the first moving frame 540 in the first-axis direction (Z-axis direction).

That is, the second moving portion 533 may be a fixed member that may not move in the second-axis direction (X-axis direction) and the third-axis direction (Y-axis direction) movement, in other words, the second moving portion 533 may not move during shake correction, and the second moving portion (533) may be spaced apart from the first moving frame (540) so as not to interfere with the second-axis direction (X-axis direction) and the third-axis direction (Y-axis direction) movement of the first moving frame (540).

Meanwhile, the first moving portion 531 may also be moved in the first-axis direction (Z-axis direction) by the bridge portion 532.

The bridge portion 532 may be formed of a flexible material and may be a portion supporting the movement of the image sensor S.

The bridge portion 532 may be disposed between the first moving portion 431 and the second moving portion 533.

The bridge portion 532 may include a plurality of bridge elements. The plurality of bridge elements may be spaced apart by a plurality of slits and may extend along the perimeter of the first moving portion 531.

The bridge portion 532 may be connected to the first moving portion 531 and the second moving portion 533 through connecting portions 534a and 534b.

In an embodiment, the connecting portions 534a and 534b may be formed of a rigid material.

In an embodiment, the connecting portions may be spaced apart in the third-axis direction (Y-axis direction) and may include a first connecting portion 534a connecting the bridge portion 532 and the first moving portion 531. For example, the first connecting portion 534a may partially extend from the first moving portion 531 in the third-axis direction Y-axis direction. The first connecting portion 534a may be connected to the first moving portion 531 and spaced apart from the second moving portion 533.

In addition, the connecting portion may include a second connecting portion (534b) that is spaced apart in the second-axis direction (X-axis direction) and connects the bridge portion (532) and the second moving portion (533). For example, the second connecting portion 534b may partially extend from the second moving portion 533 in the second-axis direction (X-axis direction). The second connecting portion 534b may be connected to the second moving portion 533 and spaced apart from the first moving portion 531.

In an embodiment, when the image sensor S is moved in the second-axis direction (X-axis direction), a plurality of bridge elements connected to the second moving portion 533 may bend. In addition, when the image sensor S moves in the third-axis direction (Y-axis direction), the plurality of bridge elements connected to the first moving portion 531 may bend.

Meanwhile, referring to FIG. 5, the sensor substrate 530 may be coupled with a connecting substrate 570. Details regarding the connecting substrate 570 will be described later.

The first moving frame 540 may have a shape with one side open.

In an embodiment, the first moving frame 540 may be formed in a ‘⊏’ shape and may be disposed such that one open side is adjacent to the connecting substrate 570.

The first moving frame 540 may be moved in a direction parallel to the imaging surface of the image sensor S, that is, in the second-axis direction (X-axis direction) and the third-axis direction (Y-axis direction).

The first moving frame 540 may be coupled with the sub-housing SH in which the image sensor S is disposed, and may be coupled with the first moving portion 531 of the sensor substrate 530 through the sub-housing SH. They may move together in the second-axis direction (X-axis direction) and the third-axis direction (Y-axis direction).

A first shake correction driving portion 563 may generate driving force to move the first moving frame 540 or the like in the second-axis direction (X-axis direction).

The first shake correction driving portion 563 may include a first shake correction magnet 5631 and a first shake correction coil 5633 shown in FIG. 4.

In an embodiment, the first shake correction magnet 5631 may be disposed on the first moving frame 540, and the first shake correction coil 5633 may be mounted on a main substrate 580 and disposed in the housing 510.

The first shake correction magnet 5631 and the first shake correction coil 5633 may face each other in the second-axis direction (X-axis direction).

When power is applied to the first shake correction coil 5633, the first moving frame 540 or the like may be moved in the second-axis direction (X-axis direction) by electromagnetic force between the first shake correction magnet 5631 and the first shake correction coil 5633.

In an embodiment, the first shake correction magnet 5631 may be a movable member disposed in the first moving frame 540 and moving together with the first moving frame 540, and the first shake correction coil 5633 may be a fixed member disposed in the housing 510.

The first shake correction driving portion 563 may include a position sensor (or second position sensor) 5635 detecting the position of the first moving frame 540. For example, the position sensor 5635 may be a hall sensor.

The position sensor 5635 may be disposed to face the first shake correction magnet 5631. For example, the position sensor 5635 may be mounted on the main substrate 580 together with the first shake correction coil 5633.

The second shake correction driving portion 565 may generate driving force to move the first moving frame 540 or the like in the third-axis direction (Y-axis direction).

The second shake correction driving portion 565 may include a second shake correction magnet 5651 and a second shake correction coil 5653.

In an embodiment, the second shake correction magnet 5651 may be disposed on the first moving frame 540, and the second shake correction coil 5653 may be mounted on the main substrate 580 and disposed in the housing 510.

The second shake correction magnet 5651 and the second shake correction coil 5653 may face each other in the third-axis direction (Y-axis direction).

When power is applied to the second shake correction coil 5653, the first moving frame 540 or the like may be moved in the third-axis direction (Y-axis direction) by the electromagnetic force between the second shake correction magnet 5651 and the second shake correction coil 5653.

In an embodiment, the second shake correction magnet 5651 may be the movable member disposed on the first moving frame 540 and moving together with the first moving frame 540, and the second shake correction coil 5653 may be a fixed member disposed in the housing 510.

The second shake correction driving portion 565 may include a position sensor (or a third position sensor) 5655 detecting the position of the first moving frame 540. For example, the position sensor 5655 may be a hall sensor.

The position sensor 5655 may be disposed to face the second shake correction magnet 5651. For example, the position sensor 5655 may be mounted on the main substrate 580 together with the first shake correction coil 5653.

The second moving frame 550 may have an internal space and be open in the first-axis direction (Z-axis direction).

In an embodiment, the internal space of the second moving frame 550 may sequentially accommodate the first moving frame 540 and the sensor substrate 530 in the first-axis direction (Z-axis direction).

In addition, a stopper 590 may be coupled to the second moving frame 550 to cover one side of the first moving frame 540. For example, the stopper 590 may be disposed to cover one side of the first moving frame 540 facing the sensor substrate 530.

The stopper 590 may prevent the first moving frame 540 accommodated in the second moving frame 550 from being separated from the second moving frame 550 due to impact or the like.

The second moving frame 550 may be moved in a direction perpendicular to the imaging surface of the image sensor S, i.e., in the first-axis direction (Z-axis direction).

The second moving frame 550 may be coupled with the second moving portion 533 of the sensor substrate 530. The second moving portion 533 may be moved in the first-axis direction (Z-axis direction) together with the second moving frame 550.

When the second moving portion 533 moves in the first-axis direction (Z-axis direction), the first moving portion 531 may also be moved in the first-axis direction (Z-axis direction) by the bridge portion 532, and accordingly, the image sensor S may also be moved in the first-axis direction (Z-axis direction).

In other words, when the second moving frame 550 moves in the first-axis direction (Z-axis direction), the configurations accommodated in the second moving frame 550 can also be moved in the first-axis direction (Z-axis direction).

Meanwhile, according to an embodiment of the present disclosure, a plate spring 535 may be further comprised to supplement the coupled structure of the second moving frame 550 and the second moving portion 533 of the sensor substrate 530.

The focus adjustment driving portion 561 may generate driving force to move the second moving frame 550 or the like in the first-axis direction (Z-axis direction).

The focus adjustment driving portion 561 may include a focus adjustment magnet 5611 and a focus adjustment coil 5613.

In an embodiment, the focus adjustment magnet 5611 may be disposed in the second moving frame 550, and the focus adjustment coil 5613 may be mounted on the main substrate 580 and disposed in the housing 510.

The focus adjustment magnet 5611 and the focus adjustment coil 5613 may face each other in the second-axis direction (X-axis direction).

When power is applied to the focus adjustment coil 5613, the second moving frame 550 or the like may be moved in the first-axis direction (Z-axis direction) by the electromagnetic force between the focus adjustment magnet 5611 and the focus adjustment coil 5613.

In an embodiment, the focus adjustment magnet 5611 may be a movable member disposed on the second moving frame 550 and moved together with the second moving frame 550, and the focus adjustment coil 5613 may be a fixed member disposed in the housing 510.

The focus adjustment driving portion 561 may include a position sensor (or first position sensor) 5615 detecting the position of the second moving frame 550. For example, the position sensor 5615 may be a hall sensor.

The position sensor 5615 may be disposed to face the focus adjustment magnet 5611. For example, the position sensor 5615 may be mounted on the main substrate 580 together with the focus adjustment coil 5613.

The second moving frame 550 may move in the first-axis direction (Z-axis direction) about to the housing 510.

A plurality of ball members B may be disposed between the second moving frame 550 and the housing 510 to reduce friction when the second moving frame 550 moves.

The plurality of ball members B may be spaced apart with the focus adjustment magnet 5611 therebetween.

The plurality of ball members B may include a plurality of balls (spheres) disposed in the first-axis direction (Z-axis direction). The plurality of ball members B may be rolling in the first-axis direction (Z-axis direction) when the second moving frame 550 is moved in the first-axis direction (Z-axis direction).

FIG. 9 is a diagram illustrating a ball guide portion according to an embodiment of the present disclosure.

Referring to FIG. 9, a plurality of ball members B may be accommodated in guide grooves provided in the second moving frame 550 and the housing 510, respectively.

In an embodiment, the second moving frame 550 may be provided with a first guide groove G1 and a second guide groove G2, and the housing 510 may be provided with a third guide groove G3 and a fourth guide groove G4.

The first guide groove G1 may face the third guide groove G3, the second guide groove G2 may face the fourth guide groove G4, and the plurality of ball members B may be disposed between them.

The first to fourth guide grooves, G1 to G4 may be extended in the first-axis direction (Z-axis direction). Additionally, a portion among the first to fourth guide grooves, G1 to G4 may have different cross-sectional shapes.

Meanwhile, a yoke 5617 may be disposed in the housing 510. In detail, the yoke 5617 may be disposed to cover the opposite surface of one surface of the main substrate 580 on which the focus adjustment coil 5613 is mounted, i.e., the other surface of the main substrate 580.

The yoke 5617 may be disposed facing the focus adjustment magnet 5611 with the focus adjustment coil 5613 therebetween.

The yoke 5617 may generate force with the focusing magnet 5611. For example, attractive force may be applied between the yoke 5617 and the focus adjustment magnet 5611 in a direction facing each other, based on the drawing, in the second-axis direction (X-axis direction).

By the attractive force generated between the yoke 5617 and the focus adjustment magnet 5611, the plurality of ball members B may maintain contact with the second moving frame 550 and the guide groove provided in the housing (510) while being accommodated therein.

According to an embodiment of the present disclosure, the movement of the image sensor S or the like during shake correction and focus adjustment may be supported by the connecting substrate 570 in addition to the bridge portion 532 of the sensor substrate 530 and the plurality of ball members B described above.

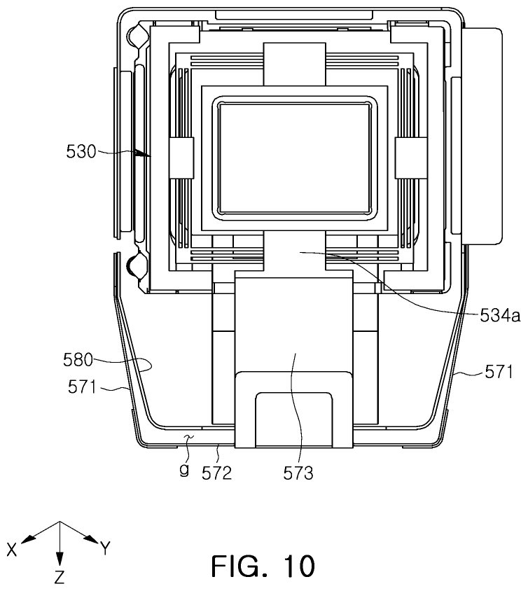

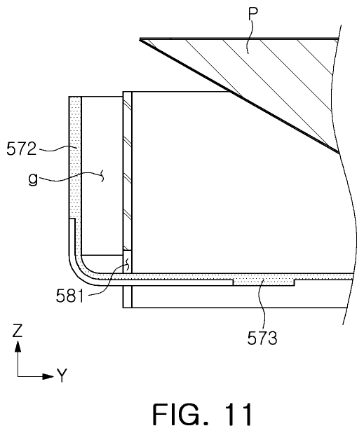

FIG. 10 and FIG. 11 are diagrams illustrating a connecting substrate according to an embodiment of the present disclosure.

The connecting substrate 570 may be formed of a flexible material to support the movement of the image sensor S or the like.

Referring to FIG. 11 or the like, the connecting substrate 570 may be disposed to surround at least a portion of the main substrate 580 from the outside of the main substrate 580.

The connecting substrate 570 may be coupled with the sensor substrate 530 and the main substrate 580.

The connecting substrate 570 may be disposed in the housing 510 by being coupled with the main substrate 580.

In detail, the connecting substrate 570 may be coupled with a first connecting portion 534a of the sensor substrate 530 and the main substrate 580. Both the first connecting portion 534a and the main substrate 580 may be formed of a rigid material. The connecting substrate 570 may support the movement of the image sensor S or the like while being coupled with them.

The connecting substrate 570 may be disposed with a gap G in at least one of the first-axis direction (Z-axis direction), the second-axis direction (X-axis direction), and the third-axis direction (Y-axis direction) from the main substrate 580.

Accordingly, when the image sensor S or the like is moved, the connecting substrate 570 may support the movement of the image sensor S or the like by moving about to the main substrate 580 within the range of the gap G formed between them. In this case, the movement amount of the image sensor S or the like may be increased by the movement amount of the connecting substrate 570.

That is, according to an embodiment of the present disclosure, a driving distance of the image sensor S may be improved during focus adjustment and shake correction.

The connecting substrate 570 may include a first portion 571 coupled with the main substrate 580, a second portion 572 extending between the first portion 571, and a third portion 573 coupled with the first connecting portion 534a of the sensor substrate 530 and connected to the second portion 572.

The first portion 571 may include two parts spaced apart in the second-axis direction (X-axis direction). The two parts may each be coupled with the main substrate 580. Additionally, either of the two parts may include a connection portion, and the connection portion may be coupled with the main substrate 580.

The first portion 571 may be disposed with a gap G approximately in the second-axis direction (X-axis direction) from a portion of the main substrate 580 disposed on the inside of the first portion 571.

In an embodiment, when the image sensor S or the like moves in the second-axis direction (X-axis direction), the first portion 571 may support the movement of the image sensor S or the like by moving within the range of the gap G formed in the second-axis direction (X-axis direction) between the first portion 571 and the main substrate 580.

The second portion 572 may extend between two parts of the first portion 571 spaced apart in the second-axis direction (X-axis direction). Accordingly, the second portion 572 may be in a form extended in the second-axis direction (X-axis direction).

The second portion 572 may be disposed with a gap G approximately in the third-axis direction (Y-axis direction) from a portion of the main substrate 580 disposed on the inside of the second portion 572.

In an embodiment, when the image sensor S or the like moves in the third-axis direction (Y-axis direction), the second portion 572 may support the movement of the image sensor S or the like by moving within the range of the gap G formed between the second portion 572 and the main substrate 580 in the third-axis direction (Y-axis direction).

One side of a third portion 573 may be coupled with the first connecting portion 534a of the sensor substrate 530 and the other side may be coupled with the second portion 572.

The third portion 573 may extend in the third-axis direction (Y-axis direction) between the first connecting portion 534a and the second portion 572, and the other side of a third portion 573 coupled with the second portion 572 may be formed to be curved at least partially by approximately 90 degrees.

Meanwhile, at the portion where the third portion 573 is curved to be coupled with the second portion 572, the third portion 573 may interfere with the portion of the main substrate 580 disposed on the inside of the second portion 572.

To prevent this, the main substrate 580 may include an avoidance groove 581 in the first-axis direction (Z-axis direction) in a portion overlapping with the third portion 573.

A gap G may be formed between the third portion 573 and the avoidance groove 581 in the first-axis direction (Z-axis direction).

In an embodiment, when the image sensor S or the like is moved in the first-axis direction (Z-axis direction), the third portion 573 may support the movement of the image sensor S or the like by moving within a range of a gap G formed in the first-axis direction (Z-axis direction) between the third portion 573 and the avoidance groove 581 of the main substrate 580.

A sensor shifting actuator and a camera module including the same according to an embodiment of the present disclosure may precisely adjust focus and correct for shake with a relatively small driving force.

An aspect of the present disclosure provides a sensor shifting actuator capable of precisely performing focus adjustment and shake correction and a camera module including the same.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sensor shifting actuator comprising:
a housing having an internal space;
an image sensor, accommodated in the housing, having an imaging surface;
a first moving frame, accommodated in the housing, configured to be movable in a direction parallel to the imaging surface, together with the image sensor;
a second moving frame, accommodated in the housing, configured to be movable in a direction perpendicular to the imaging surface, together with the image sensor and the first moving frame;
a bridge portion configured to curve in at least a portion thereof and support a movement of the image sensor in the direction parallel to the imaging surface; and
a plurality of ball members, disposed between the second moving frame and the housing, configured to support another movement of the image sensor in the direction perpendicular to the imaging surface.

2. The sensor shifting actuator of claim 1, wherein a sensor substrate disposed on one side of the image sensor comprises
a first moving portion coupled with the first moving frame,
a second moving portion coupled with the second moving frame and spaced apart from the first moving portion, and
the bridge portion disposed between the first moving portion and the second moving portion.

3. The sensor shifting actuator of claim 2, wherein
the first moving portion and the second moving portion are formed of a rigid material, and the bridge portion is formed of a flexible material.

4. The sensor shifting actuator of claim 2,
further comprising a connecting substrate configured to support the movement and the other movement of the image sensor, the first moving frame, and the second moving frame, and
wherein one side of the connecting substrate is connected to the sensor substrate and another side of the connecting substrate is disposed in the housing.

5. The sensor shifting actuator of claim 4, wherein
the sensor substrate comprises
a first connecting portion extending from the first moving portion and connecting the first moving portion and the bridge portion, and,
a second connecting portion extending from the second moving portion and connecting the second moving portion and the bridge portion, and
wherein the one side of the connecting substrate is connected with the first connecting portion.

6. The sensor shifting actuator of claim 4, further comprising a main substrate disposed in the housing,
wherein the other side of the connecting substrate is coupled to the main substrate, and
the connecting substrate is disposed to surround a portion of the main substrate while maintaining a gap therebetween.

7. The sensor shifting actuator of claim 6, wherein the connecting substrate comprises
a first portion disposed with a gap between the main substrate in a first direction parallel to the imaging surface,
a second portion disposed with a gap between the main substrate in a second direction parallel to the imaging surface and perpendicular to the first direction, and
a third portion disposed with a gap between the main substrate in a third direction perpendicular to the imaging surface, and
wherein the first portion is connected to the housing, and the third portion is connected to the sensor substrate.

8. The sensor shifting actuator of claim 7, wherein
a surface of the main substrate comprises an avoidance groove extending therethrough in the third direction in a portion overlapping with the third portion, and
wherein a portion of the third portion is disposed in the avoidance groove.

9. The sensor shifting actuator of claim 1, further comprising:
a first shake correction magnet and a second shake correction magnet disposed on the first moving frame; and
a first shake correction coil and a second shake correction coil disposed in the housing to face the first shake correction magnet and the second shake correction magnet, respectively.

10. The sensor shifting actuator of claim 1, further comprising:
a focus adjustment magnet disposed on the second moving frame; and
a focus adjustment coil disposed in the housing to face the focus adjustment magnet.

11. The sensor shifting actuator of claim 10, further comprising a yoke disposed in the housing to face the focus adjustment magnet.

12. A camera module comprising:
a lens module comprising at least one lens disposed along an optical axis direction;
an image sensor having an imaging surface;
a reflective member configured to reflect light toward the image sensor; and
a sensor shifting actuator configured to move the image sensor in a direction parallel to the imaging surface and a direction perpendicular to the imaging surface with respect to the reflective member,
wherein the sensor shifting actuator comprises
a bridge portion, disposed to be curved in at least a portion thereof, configured to support movement of the image sensor in the direction parallel to the imaging surface, and
a plurality of ball members configured to support movement of the image sensor in the direction perpendicular to the imaging surface while rolling in the direction perpendicular to the imaging surface.

13. The camera module of claim 12, wherein the sensor shifting actuator further comprises
a first moving frame configured to be movable in the direction parallel to the imaging surface, together with the image sensor, and
a second moving frame configured to be movable in the direction perpendicular to the imaging surface, together with the image sensor and the first moving frame.

14. The camera module of claim 13, wherein the sensor shifting actuator comprises a sensor substrate disposed on one side of the image sensor, and
wherein the sensor substrate comprises
a first moving portion coupled with the first moving frame,
a second moving portion coupled with the second moving frame and spaced apart from the first moving portion, and
the bridge portion disposed between the first moving portion and the second moving portion.

15. The camera module of claim 14, wherein the sensor shifting actuator comprises
a main substrate disposed in a housing in which the image sensor is accommodated, and
a connecting substrate in which one side is connected to the sensor substrate and another side is connected to the main substrate,
wherein the connecting substrate is disposed to have a gap between the main substrate in at least one direction, among the direction parallel to the imaging surface and the direction perpendicular to the imaging surface, and
wherein the connecting substrate is configured to bend in at least a portion thereof when the image sensor moves.

16. The camera module of claim 12, wherein the reflective member is a parallelogram shaped prism.
